(19) United States
(12) Patent Application Publication
(10) Pub. No.: US 2008/0156370 A1
(43) Pub. Date: Jul. 3, 2008

(54) Heterocontact Solar Cell with Inverted Geometry of its Layer Structure

(75) Inventors: Ossamah Abdallah, Berlin (DE); Guiseppe Citarella, Frankfurt/Oder (DE); Marinus Kunst, Berlin (DE); Frank Wuensch, Berlin (DE)

Correspondence Address: DARBY & DARBY P.C., P.O. BOX 770, Church Street Station, New York, NY, 10008-0770, US

(73) Assignee: Hahn-Meitner-Institut Berlin GmbH, Berlin (DE)

(21) Appl. No.: 11/912,240

(22) PCT Filed: Apr. 11, 2006
(86) PCT No.: PCT/DE06/00670

§ 371 Date: Oct. 22, 2007

(30) Foreign Application Priority Data
Apr. 20, 2005 (DE) 10 2005 019 225.4

(51) Int. Cl. H01L 31/00

(52) U.S. Cl. 136/258; 257/436

(57) ABSTRACT

A heterocontact solar cell in a layer structure. The solar cell includes an absorber made of a p-type and/or n-type doped crystalline semiconductor material. The cell also includes an emitter made of an amorphous semiconductor material that is oppositely doped relative to the absorber. Also included is an intrinsic interlayer made of an amorphous semiconductor material between the absorber and the emitter. The cell includes a cover layer on the side of the absorber facing a light. A first ohmic contact structure including a minimized shading surface on the side of the absorber facing the light and a second ohmic contact structure on a side of the absorber facing away from the light are also included. The layer structure has an inverted geometry such that the emitter is on a side of the absorber facing away from the light and the cover layer is configured as a transparent antireflective layer and as a passivation layer of the absorber, the passivation layer forms a surface field that reflects minority charge carriers, the first ohmic contact structure penetrating the transparent antireflective layer and the second ohmic contact structure configured over a surface area of the emitter.

### CROSS REFERENCE TO RELATED APPLICATIONS

This is a U.S. national phase application under 35 U.S.C. §371 of International Patent Application No. PCT/DE2006/000670, filed Apr. 11, 2006, and claims benefit of German Patent Application No. 10 2005 019 225.4, filed Apr. 20, 2005, which is incorporated by reference herein. The Internation Application was published in German on Oct. 26, 2006 as WO 2006/111138 A1 under PCT Article 21(2).

The present invention relates to a heterocontact solar cell in a layer structure.

### BACKGROUND

Heterocontact solar cells with crystalline and amorphous silicon are acquiring ever-greater technical significance. The usual structuring of a heterocontact solar cell is disclosed, for example, in Publication I by K. Brendel et al. “Interface properties of a-Si:H/c-Si heterostructures”(Annual Report 2003, Hahn-Meitner-Institut, 78/79). On its side facing the light, the central absorber, made of crystalline, p-doped silicon (c-Si(p)) and microcrystalline silicon (μc-Si), has an emitter made of amorphous, n-doped amorphous silicon “alloyed” or enriched with hydrogen (a-Si:H(n⁺)) and a transparent conductive oxide layer (TOC) as the cover layer under finger-like front contacts. The emitter on the top of the absorber facing the light absorbs radiation that then can no longer reach the absorber. On the bottom of the absorber facing away from the light, there is an amorphous, heavily p-doped silicon layer enriched with hydrogen (a-Si:H(p⁺)) between the absorber and a full-surface back contact for purposes of forming a surface field that reflects minority charge carriers (back surface field—BSF).

As is the case with solar cells, the heterocontact solar cell with the familiar layer structure geometry, where the emitter is positioned on the top of the absorber facing the light, sustains losses when the light energy that enters the solar cell is converted into electrical energy. Basically, due to their disordered structure, amorphous areas have worse transport properties for charge carriers than crystalline areas do. A loss process in the conversion chain consists of the fact that not all of the photons of the incident radiation in an “active” region of the solar cell are converted into electron-hole pairs. The term “active region” here refers to the zone in the solar cell where the electrons and holes are collected since their life span is long enough and they can then flow out via the ohmic contact system. A prerequisite for a solar cell to function properly is for the largest possible radiation fraction to be absorbed in the active region. In the case of heterocontact solar cells, this active region is the absorber made of crystalline silicon whereas, in contrast, the heavily doped emitter made of amorphous silicon through which the light enters the absorber is designated as the “inactive region” because the electrons and holes generated in this layer only have a relatively short life span, as a result of which they can hardly be collected. Due to the high absorption coefficient of the amorphous emitter material, a considerable portion of the incident sunlight is absorbed in the emitter.

In order to reduce the above-mentioned loss processes in heterocontact solar cells having a conventional layer structure geometry and an emitter on the top of the absorber facing the light, European patent application EP 1 187 223 A2, describes for the so-called “HIT” solar cells (heterojunction with intrinsic thin layer) made by the Sanyo company the approach of either reducing the thickness of the emitter made of heavily doped amorphous silicon, whereby a minimum layer thickness of 5 nm has to be maintained so that the pn heterocontact can be completely formed, or else of reducing the light absorption in the emitter by increasing the bandgap. Towards this end, the amorphous silicon of the emitter is alloyed with carbon. The generic heterocontact solar cell described in European patent application EP 1 187 223 A2 has a layer structure with an n-type doped crystalline silicon wafer in the center as the absorber. On both sides of the absorber, a heterocontact to the adjacent amorphous silicon layers is established. On the side of the absorber facing the light, there are two intrinsic interlayers, namely, the amorphous emitter and a transparent conductive electrode (ITO) as the cover layer. On the side of the absorber facing away from the light, at least two more amorphous layers are provided in front of a collecting back electrode for purposes of creating a BSF, whereby one layer is not doped whereas the other is heavily doped like the n-type absorber. Both sides of the heterocontact solar cell have grid-like contact systems on the ITO layers that collect charge carriers.

Therefore, the HIT solar cell also has a transparent conductive layer (TCO, ITO) on the top facing the light in order to carry away the charges collected in the less conductive, amorphous emitter. Publication II by A. G. Ulyashin et al. “The influence of the amorphous silicon deposition temperature on the efficiency of the ITO/a-Si:H/c-Si heterojunction (HJ) solar cells and properties of interfaces”(Thin Solid Films 403-404 (2002) 259-362) shows that the deposition of this transparent conductive layer on the amorphous emitter is suspected of causing the electronic properties to deteriorate at the interface between the amorphous and the crystalline silicon (emitter/absorber).

Furthermore, German patent application DE 100 45 249 A1 describes a crystalline solar cell in which the crystalline emitter is arranged on the side of the absorber facing away from the light. It is configured there in the form of a strip using a production process at a high temperature and it is interleaved with crystalline strips having the opposite doping, forming a BSF. This purely crystalline, interdigitated semiconductor structure can only be created by a very complicated production process and serves exclusively for the back side contact in which the two ohmic contact structures are arranged on the bottom of the solar cells facing away from the light and are likewise interleaved. Underneath the antireflective layer that is integrated into an encapsulation and that is provided on the top of the absorber facing the light, the known solar cell has an additional passivation layer that serves to reduce the recombination of light-generated charge carriers on the front of the solar cell but that also additionally absorbs light. Other interdigitated solar cells are also described in U.S. Pat. No. 4,927,770, with very small emitter regions and in U.S. Pat. Appln. No. 2004/0200520 A1, in which larger emitter regions are provided in trenches. In the case of both interdigitated solar cells, the top facing the light is not only provided with a passivation layer and an antireflective layer, but also with a doped front layer in order to form a surface field that reflects minority charge carriers (front surface field—FSF). Especially the layer that forms the surface field—if it is a heavily doped Si layer—is highly absorptive and consequently reduces the incidence of light in the active region of the solar cell as well as the charge carrier yield. On the top facing the light, however, the formation of an FSF is particularly important since many charge carriers are generated here because of strong light incidence, and the recombination of these charge carriers has to be minimized.

German patent application DE 100 42 733 A1 describes a likewise purely crystalline thin-layer solar cell having a transparent glass superstrate on the light-incidence side and having a p-type doped polycrystalline absorber (p-pc-Si) with a contact layer between the absorber and the glass superstrate made of heavily p-doped polycrystalline silicon (p⁺-pc-Si), which concurrently serves as a transparent electrode and as a layer for structuring an FSF. The creation of the FSF and the current collection by the transparent electrode on the side facing the light, however, come at the expense of absorption losses in the entry window here as well. No provision is made for an antireflective layer on the side facing the light, so this function has to be taken over by the glass superstrate. On the side of the absorber facing away from the light, the emitter made of heavily n-doped microcrystalline silicon (n⁺-Pc-Si) with a rough surface on the opposite side is located directly on the absorber, and an aluminum layer is arranged on said surface as the back-reflective contact layer and as the electrode.

### SUMMARY

An aspect of the present invention is to provide an easy-to-produce layer structure geometry for a heterocontact solar cell that has only slight optical losses, that can dispense with a transparent conductive electrode (TCO) on the side facing the light and that nevertheless yields a conversion efficiency that, in the production of electricity from solar energy, is comparable to heterocontact solar cells having a conventional layer structure geometry. A further and alternative aspect of the present invention is to achieve a short energy recuperation time for the produced heterocontact solar cells while using little material, time and energy and while attaining a simple and cost-effective mode of production.

In an embodiment, the present invention provides a heterocontact solar cell in a layer structure. The solar cell includes an absorber made of a p-type and/or n-type doped crystalline semiconductor material. The cell also includes an emitter made of an amorphous semiconductor material that is oppositely doped relative to the absorber. Also included is an intrinsic interlayer made of an amorphous semiconductor material between the absorber and the emitter. The cell includes a cover layer on the side of the absorber facing a light. A first ohmic contact structure including a minimized shading surface on the side of the absorber facing the light and a second ohmic contact structure on a side of the absorber facing away from the light are also included. The layer structure has an inverted geometry such that the emitter is on a side of the absorber facing away from the light and the cover layer is configured as a transparent antireflective layer and as a passivation layer of the absorber, the passivation layer forms a surface field that reflects minority charge carriers, the first ohmic contact structure penetrating the transparent antireflective layer and the second ohmic contact structure configured over a surface area of the emitter.

### BRIEF DESCRIPTION OF THE DRAWINGS

Aspects of the present invention will now be described by way of exemplarary embodiments with reference to the following figures, in which:

FIG. 1 is a layer structure cross section through a heterocontact solar cell.

FIG. 2 is a diagram with a dark and light characteristic curve of a produced heterocontact solar cell.

FIG. 3 is a diagram showing a spectral quantum yield of the heterocontact solar cell according to FIG. 2.

### DETAILED DESCRIPTION

The heterocontact solar cell, according to an embodiment of the present invention, has an inverted geometry of its layer structure and thus an inverted heterocontact. The amorphous emitter is arranged on the bottom of the absorber facing away from the light. Behind the absorber, the intensity of the incident light is already reduced to such a large extent that hardly any radiation penetrates the emitter and is absorbed there, so that the absorption losses can be kept small. On the top of the absorber facing the light, the heterocontact solar cell according to an embodiment of the present invention only has a single transparent antireflective layer with improved antireflective properties as the cover layer which, since the selected material concurrently functions as an electrically active passivation layer, prevents a recombination of the charge carriers in that a surface field (FSF) that back-scatters minority charge carriers is formed. The antireflective properties of the antireflective layer are determined by the selection of its material, which has to have a refractive index (n_{ARS}) that is greater than the refractive index of air (n_{L}) but smaller than the refractive index of the crystalline semiconductor material of the absorber (n_{AB}), i.e. (n_{L<}n_{ARS}<n_{AB}). Due to the dual function of the cover layer as a transparent antireflective layer and as a passivation layer, there is no need for a transparent conductive electrode (TCO) on the side facing the light since the electrode's function of conducting current can be taken over by a fine contact grid as the top contact system. Moreover, other layers, particularly heavily doped Si-FSF layers and thus the highly absorbing passivation layers, as well as their preparation on the top of the solar cell, can all be dispensed with. Due to the elimination of additional cover layers, the manufacturing effort in terms of the use of material, time and energy is considerably reduced and simplified in the case of the heterocontact solar cell according to an embodiment of the present invention.

In contrast to interdigitated crystalline solar cells that also have a crystalline, strip-like emitter on the side of the absorber facing away from the light, the amorphous emitter of the heterocontact solar cell according to an embodiment of the present invention is configured as a contiguous layer so that it is easier to manufacture, functions efficiently and can be easily contacted. In addition, the emitter for the heterocontact solar cell is not formed by diffusing the appertaining doping species at temperatures above 900° C. [1652° F.] but rather, for instance, by means of plasma enhanced chemical vapor deposition from the gas phase (PECVD) at substrate temperatures of less than 250° C. [482° F.].

Furthermore, by separating the transparent antireflective layer and the emitter in the case of the heterocontact solar cell according to an embodiment of the present invention, the thickness of these layers can be optimized independently of each other. For instance, the layer thickness of the emitter on the bottom of the absorber facing away from the light can have a thicker layer than on the top facing the light, which yields a good, stable space charge region. The electronic properties of the active interface between the emitter and the absorber are improved as a result. When the transparent antireflective layer is produced, in turn, it is no longer necessary to take into account layers located underneath or an effect on their electronic properties.

The charge carriers generated in the absorber are separated in the space charge region on the heterocontact between the crystalline absorber and the amorphous emitter and carried away via the ohmic contact structures. In this process, the ohmic contact structure on the top of the absorber facing the light—which is configured with a minimized shading surface—penetrates the transparent antireflective layer. The other ohmic contact structure is configured over a large surface area of the emitter on the bottom of the absorber facing away from the light. Advantageously, zones that reflect charge carriers can also be configured in the absorber underneath the contact structure that penetrates the transparent antireflective layer, so that, together with the surface field (FSF) that back-scatters the charge carriers formed by the transparent antireflective layer, a continuous surface field is created on the entire surface of the absorber. In order to contact the emitter, there is no longer a need for a transparent conductive oxide layer (TCO, e.g. ITO) as the electrode whose deposition on the amorphous emitter is suspected of causing a deterioration of the electronic properties at the heterotransition (see above). This technical difficulty is avoided in the invention by a gentle metallization of the amorphous emitter that allows good contact over a large surface area in order to create the large-surface contact structure, for example, by thermal vaporization. In this context, the large-surface contact structure can cover the entire bottom of the emitter or substantial surface areas of it by using a masking technique.

The above-mentioned advantages have a particularly favorable effect on heterocontact solar cells according to an embodiment of the present invention having an inverted heterotransition if the absorber is made of n-type doped crystalline silicon and the emitter is made of p-type doped amorphous silicon having an intrinsic, that is to say, undoped, amorphous interlayer. When such materials are selected, a technically easy-to-handle, n-conductive absorber made of silicon and having good transport properties as well as a long charge carrier life span is achieved, and the silicon can be configured to be monocrystalline, multicrystalline or else microcrystalline. Through the selection of such a material system, the passivation layer that forms the FSF can be made not of silicon oxide but rather of silicon nitrite, whose optical refractive index is between that of air and of silicon, so that the passivation layer at the same time functions as a good transparent antireflective layer. Such a dual-function transparent antireflective layer is also possible if the absorber is doped so as to be p-conductive. The refractive index of the selected material has to once again be between that of air and of silicon, and the material has to have a passivating effect on the absorber. Moreover, the bottom of the silicon absorber facing away from the light can be passivated by the emitter made of amorphous silicon in a simple manner employing a low-temperature process, which translates into very slight interface recombination since open bonds, so-called “dangling bonds”, are chemically saturated very efficiently. The saturation with amorphous silicon, whose bandgap lies well above that of crystalline silicon, yields a very good pn-heterocontact transition. The amorphous silicon of the emitter, in contrast, displays a pronounced absorption and recombination behavior. The arrangement of a thin emitter behind the active region is thus optimal. Moreover, one of the ohmic contact structures can be configured on the top of the absorber facing the light as a contact finger or contact grid made of silver or aluminum, while the other ohmic contact structure can be configured on the emitter as a thin, flat metal layer of gold or another suitable material. Even though both of these noble metals are relatively expensive, they are employed in such small quantities that preference should be given to their use in view of their excellent conductivity and processing properties. Furthermore, when large-surface structures are used, it is conceivable to thicken the contacts with cheaper metals. Furthermore, the absorber can be configured as a self-supporting wafer, especially a silicon wafer, in a layer that is relatively thick. The solar cell according to the invention, however, can also be made using the thin-layer technique, that is to say, with individual layers having a thickness in the nm or μm range and they can receive the requisite stability from a glass substrate on the bottom of the absorber facing away from the light. Other example arrangements, material systems and production processes are described below.

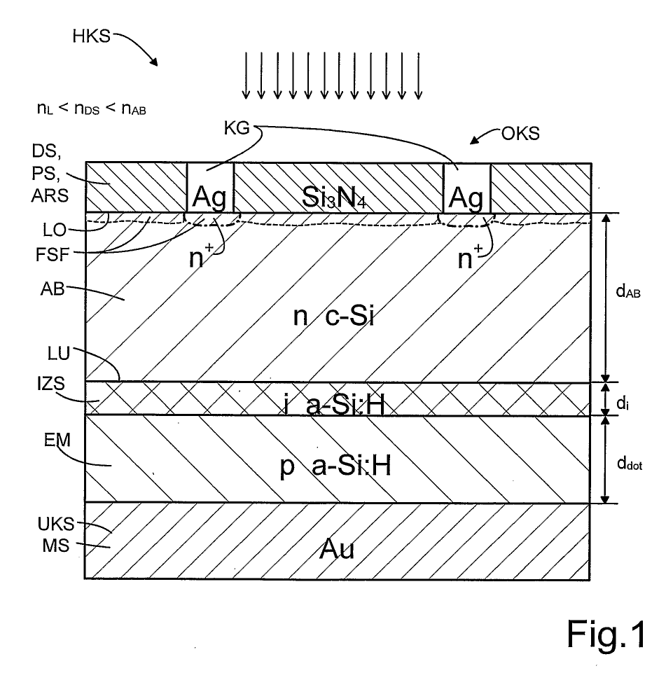

FIG. 1 shows a heterocontact solar cell HKS with an absorber AB whose top LO facing the light is struck by light radiation (either natural or artificial, visible and/or invisible) (arrows). The absorber AB includes a self-supporting wafer having the layer thickness d_{AB} and made of n-type doped crystalline silicon n c-SI. Here, the employed silicon can be configured to be monocrystalline, polycrystalline, multicrystalline or microcrystalline and can be produced accordingly.

A transparent antireflective layer ARS made of silicon nitrite Si₃N₄ is arranged as a cover layer DS on the top LO of the absorber AB facing the light, and this antireflective layer ARS concurrently functions as a passivation layer PS on the absorber AB, and a surface field FSF (depicted with a broken line in FIG. 1) that back-scatters charge carriers is formed in order to prevent recombination of the charge carriers on the light incidence side. The dual function of the cover layer DS results from the selection of its material as a function of the absorber material. The antireflective properties of the transparent antireflective layer are determined by the selection of its optical refractive index n_{ARS} between the refractive index of air n_{L} and the refractive index of the absorber material n_{AB}, i.e. (n_{L}<n_{ARS}<n_{AB}). The passivating properties depend on the electrical effect that the selected material has on the absorber surface. Due to the single cover layer DS on the absorber AB, the photon losses through absorption are considerably reduced in comparison to heterocontact solar cell structures where the emitter EM is arranged on the top LO of the absorber AB facing the light. Moreover, when the transparent antireflective layer ARS is structured, there is no risk of detrimentally affecting the underlying layers and their electronic properties.

In the case of the heterocontact solar cell HKS with inverted geometry of its layer structure, the emitter EM is arranged on the bottom LU of the absorber AB facing away from the light. In the selected embodiment, the emitter EM is made of amorphous silicon enriched with hydrogen H and having a p-type doping p a-Si:H. Due to its inverted positioning behind the absorber AB, the emitter EM cannot absorb any light and thus its layer thickness d_{dot} can be dimensioned individually and especially can be configured so as to be sufficiently thick. However, since the mobility of the charge carriers in amorphous silicon is much less than in crystalline silicon, d_{dot} must not be too thick either. Therefore, d_{dot} can be optimized in terms of a slight series resistance on the part of the heterocontact solar cell HKS. A very thin intrinsic (undoped) interlayer IZS having the layer thickness d₁ and situated between the absorber AB and the emitter EM is made of amorphous silicon i a-Si:H in the selected embodiment.

The heterocontact solar cell HKS with inverted geometry of its layer structure has, on its top facing the light, an upper contact structure OKS that is configured in such a way that it shades the absorber AB with only a minimum surface, so that maximal light incidence is possible. For this purpose, the contact structure OKS can have a finger-like or grid-like configuration. In the selected embodiment, the upper contact structure OKS is formed by a contact grid KG made of silver Ag. The transparent antireflective layer AR is penetrated in the area of the contact grid KG so that at first no surface field FSF that reflects minority charge carriers is formed directly under the contact fingers. During the generation of the contact grid KG, however, measures (see below) can be taken that result in a heavily n-doped n⁺ insertion underneath the contact grid KG in the absorber AB in the selected embodiment, so that here, too, an FSF (depicted by a dot-dash line in FIG. 1) that reflects minority charge carriers is formed. Consequently, the entire surface of the absorber AB can be passivated.

A bottom contact structure UKS that is not exposed to the incident light is located on the bottom of the emitter EM. As a result, its shading surface does not have to be minimized, but rather it can contact the low-conductivity amorphous emitter EM over the largest possible surface area in order to collect the separated charge carriers. In the selected embodiment, the bottom contact structure UKS is configured as a thin, flat metal layer MS made of gold Au.

The heterocontact solar cell HKS with inverted geometry of its layer structure shown in FIG. 1 can be produced, for instance, according to the sequence below. Other production methods, however, can likewise be employed.

For purposes of forming the absorber AB having the layer thickness d_{AB}, according to a known standard formulation, hydrogen(H)-terminated surfaces are prepared by a wet chemical process on an absorber-sized section of a 0.7 Ωcm to 1.5 Ωcm n-doped silicon wafer. Subsequently, an approximately 70 nm-thick layer of silicon nitrite Si₃N₄ is precipitated as a transparent antireflective layer ARS onto the prepared surface by means of plasma CVD at a temperature of 325° C. to 345° C. [617° F. to 653° F.]. This layer can then be penetrated at 600° C. to 800° C. [1112° F. to 1472° F.] (firing the contacts through the transparent antireflective layer ARS) by the contact grid applied by silk-screening a commercially available silver conductive paste with a phosphorus source. Owing to the local diffusion of the phosphorus, heavily n-doped regions n⁺ are created underneath the contact grid KG and, as a surface field FSF, these regions reflect minority charge carriers, they reduce the recombination of the charge carriers generated by the light and they close the surface field FSF that reflects minority charge carriers of the transparent antireflective layer ARS in the area of the contact grid KG. As an alternative, the transparent antireflective layer ARS can be partially opened, for instance, by means of photolithographic steps, in order to ohmically contact the silicon of the absorber AB on the top LO facing the light with vapor-deposited aluminum as the contact grid KG.

After the bottom LU of the absorber AB facing away from the light undergoes an etching cleansing step using diluted hydrofluoric acid, then plasma deposition is likewise carried out to deposit amorphous silicon as the emitter EM of the solar cell SZ. This is done in two stages: firstly, undoped silicon (i a-Si:H) is grown on a thin intrinsic interlayer IS having a layer thickness dᵢ of a few nm and subsequently an emitter layer (p a-Si:H) doped with about 10,000 ppm of boron and having a thickness of 20 to 40 nm (layer thickness d_{dot}) is applied.

Then, in the next step, the bottom LU of the emitter EM facing away from the light is metallized by the vapor-deposition of an approximately 150 nm-thick metal layer MS made of gold Au, thus forming the bottom contact structure UKS, whereby its lateral extension can be determined by using masks of different sizes.

As an alternative to this, the upper contact structure OKS can be manually prepared on the transparent antireflective layer ARS by partially etching away the transparent antireflective layer ARS made of Si₃N₄, by wetting these exposed areas with a gallium-indium eutectic mixture GaIn and by subsequently encapsulating them with conductive adhesive containing silver.

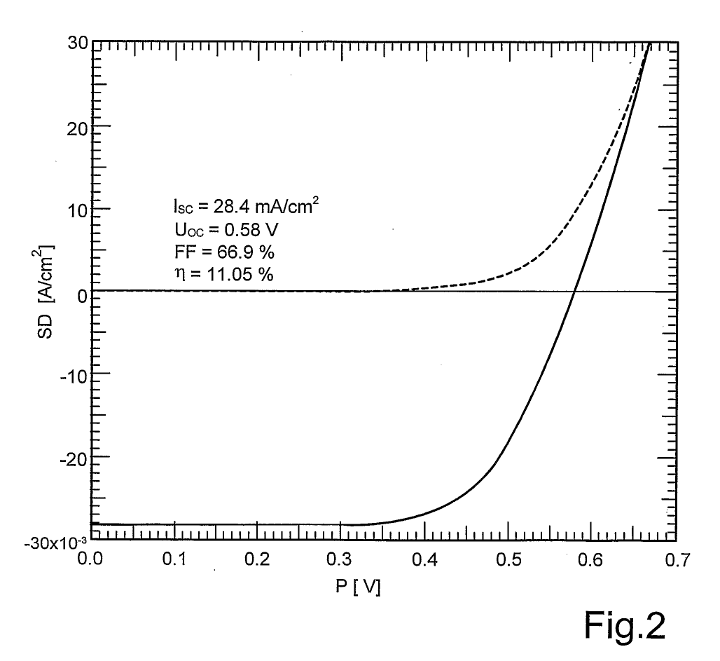

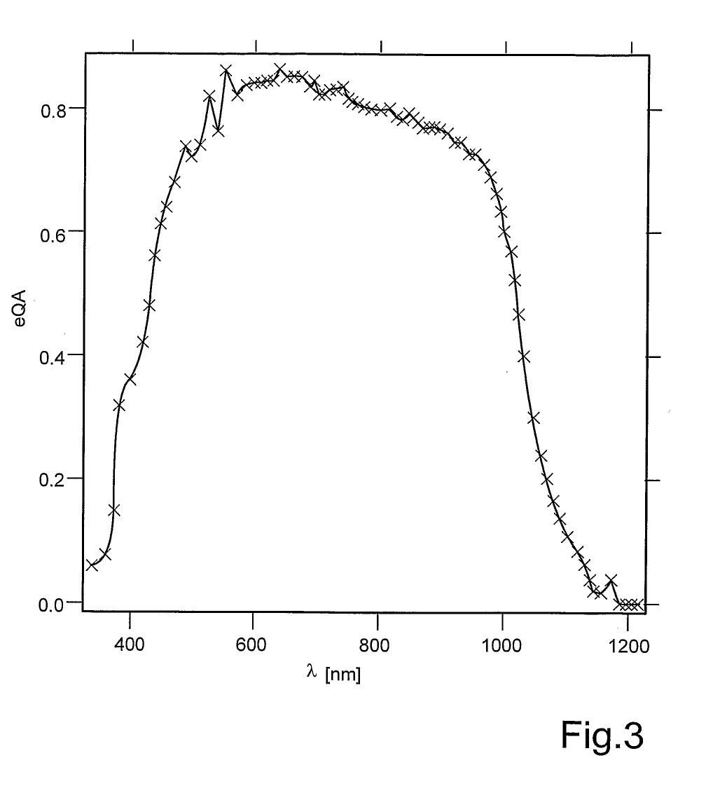

Heterocontact solar cells HKS with inverted geometry of their layer structure produced by means of the above-mentioned method according to FIG. 1 show an efficiency of more than 11.05% (FIG. 2, diagram with a dark and light characteristic line, current density SD in A/cm² above the potential P in V) at an external spectral quantum yield that is typical of crystalline silicon (FIG. 3, diagram of the spectral quantum yield for the solar cell according to FIG. 2, external quantum yield eQA above the wavelength λ in nm). The efficiency, which is limited by the relatively high series resistance, can still be markedly raised by optimizing the upper contact structure OKS.

1 to 7. (canceled)

8. A heterocontact solar cell in a layer structure, comprising:
an absorber made of at least one of a p-type and n-type doped crystalline semiconductor material;
an emitter made of an amorphous semiconductor material that is oppositely doped relative to the absorber;
an intrinsic interlayer made of an amorphous semiconductor material between the absorber and the emitter;
a cover layer on a side of the absorber facing a light;
a first ohmic contact structure including a minimized shading surface on the side of the absorber facing the light; and
a second ohmic contact structure on a side of the absorber facing away from the light,
wherein the layer structure has an inverted geometry such that the emitter is on a side of the absorber facing away from tile light and the cover layer is configured as a transparent antireflective layer and as a passivation layer of the absorber, the passivation layer forming a surface field that reflects minority charge carriers, the first ohmic contact structure penetrating the transparent antireflective layer and the second ohmic contact structure configured over a surface area of the emitter.

9. The solar cell according to claim 8, wherein regions that reflect charge carriers are formed in the absorber underneath the first ohmic contact structure.

10. The solar cell according to claim 8, wherein the absorber is made of n-type doped crystalline silicons the emitter is made of p-type doped amorphous silicon and the intrinsic interlayer is made of undoped amorphous silicon.

11. The solar cell according to claim 9, wherein the absorber is made of n-type doped crystalline silicon, the emitter is made of p-type doped amorphous silicon and the intrinsic interlayer is made of undoped amorphous silicon.

12. The solar cell according to claim 8, wherein the transparent antireflective layer is made of silicon nitrite.

13. The solar cell according: to claim 9, wherein the transparent antireflective layer is made of silicon nitrite.

14. The solar cell according to claim 10, wherein the transparent antireflective layer is made of silicon nitrite.

15. The solar cell according to claim 8, wherein the first ohmic con-tact structure is configured as at least one of a contact finger and a contact grid made of silver, and the second ohmic contact structure is configured as a thin, flat metal layer made of gold.

16. The solar cell according to claim 9, wherein the first ohmic contact structure is configured as at least one of a contact finger and a contact grid made of silver, and the second ohmic contact structure is configured as a thin, flat metal layer made of gold.

17. The solar cell according to claim 10, wherein the first ohmic contact structure is configured as at least one of a contact finger and a contact grid made of silver, and the second ohmic contact structure is configured as a tin flat metal layer made of gold.

18. The solar cell according to claim 12, wherein the first ohmic contact structure is configured as at least one of a contact finger and a contact grid made of silver, and the second ohmic contact structure is configured as a thin, flat metal layer made of gold.

19. The solar cell according to claim 8, wherein the absorber includes a self-supporting wafer.

20. The solar cell according to claim 9, wherein the absorber includes a self-supporting wafer.

21. The solar cell according to claim 10, wherein the absorber includes a self-supporting wafer.

22. The solar cell according to claim 12, wherein the absorber includes a self-supporting wafer.

23. The solar cell according to claim 15, wherein the absorber includes a self-supporting wafer.

24. The solar cell according to claim 8, wherein the layers of the solar cell have a thin-layer structuring and further comprising a load-bearing glass substrate, the load-bearing glass substrate being on the side of the absorber facing away from the light.

25. The solar cell according to claim 9, wherein the layers of the solar cell have a thin-layer structuring and further comprising a load-bearing glass substrate, the load-bearing glass substrate being on the side of the absorber facing away from the light.

26. The solar cell according to claim 10, wherein the layers of the solar cell have a thin-layer structuring and further comprising a load-bearing glass substrate, the load-bearing glass substrate being on the side of the absorber facing away from the light.

27. The solar cell according to claim 12, wherein the layers of the solar cell have a thin-layer structuring and further comprising a load-bearing glass substrate, the load-bearing glass substrate being on the side of the absorber facing away from the light.
